(19) United States
(12) Patent Application Publication
(10) Pub. No.: US 2021/0017336 A1
(43) Pub. Date: Jan. 21, 2021

(54) POLYAMIC ACID COMPOSITION, POLYIMIDE FILM, AND COPPER CLAD LAMINATE

(71) Applicant: Zhen Ding Technology Co., Ltd., Tayuan (TW)

(72) Inventors: SZU-HSIANG SU, Taoyuan (TW); PEI-JUNG WU, Taoyuan (TW); KUAN-WEI LEE, Tayuan, Taoyuan (TW); SHOU-JUI HSIANG, Tayuan (TW)

(21) Appl. No.: 16/561,401

(22) Filed: Sep. 5, 2019

(30) Foreign Application Priority Data
Jul. 16, 2019 (CN) 201910641390.3

(51) Int. Cl. C08G 73/10; C08L 79/08; C09K 19/12; C09K 19/30; B32B 15/20; B32B 15/088

(52) U.S. Cl. CPC C08G 73/1067; C08L 79/08; C09K 19/12; C09K 19/3003; C09K 2019/3009; B32B 15/088; C08L 2203/16; C09K 2019/122; B32B 15/20

(57) ABSTRACT

A polyamic acid composition is polymerized by dianhydride monomers and diamine monomers. A range of molar ratio of the dianhydride monomers to the diamine monomers is from 0.9 to 1.1. The diamine monomers have a combination of specific functional groups containing at least one nitrogen heterocycle structure, at least one liquid crystal structure, and at least one soft structure, wherein the diamine monomer containing nitrogen heterocycle structure has a molar weight percentage of 3% to 8% of a total molar weight of the diamine monomers, and the diamine monomers containing at least one liquid crystal structure and at least one soft structure have a molar weight percentage of 92% to 97% of the total molar weight of the diamine monomers. The disclosure further relates to a polyimide film, a copper clad laminate, and a printed circuit board.

### FIELD

The subject matter of the application relates to a polyamic acid composition, a polyimide film using the polyamic acid composition, and a copper clad laminate using the polyimide film.

### BACKGROUND

Printed circuit board (PCB) is usually made by at least one copper clad laminate and at least one electronic component. A copper clad laminate includes a polyimide film and at least one copper foil attached to the surface of the polyimide film. The polyimide film is formed by coating a polyamic acid to the surface of the copper foil. During the process of making the printed circuit board, a portion of the copper foil will be removed from a region of the polyimide film, thereby exposing the region of the polyimide film. The exposed region of the polyimide film needs to be created accurately, to allow a CCD camera to accurately position the electronic component. The higher transparency of the exposed region, the better accurately positioning of the electronic component. In the copper clad laminate, the lower surface roughness of the copper foil, the higher transparency of the exposed region of the polyimide film. Conversely, the lower surface roughness of the copper foil, the weaker combined strength between the copper foil and the polyimide film.

Therefore, there is room for improvement in the art.

### BRIEF DESCRIPTION OF THE DRAWINGS

Implementations of the present disclosure will now be described, by way of embodiments, with reference to the attached figures.

FIG. 1 is a flowchart of a method for manufacturing a polyamic acid composition in accordance with an embodiment.

FIG. 2 is a cross-section view of an embodiment of a copper clad laminate.

FIG. 3 is a cross-section view of a printed circuit board according to an embodiment of the present application.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale, and the proportions of certain portions may be exaggerated to better illustrate details and features of the present disclosure.

The disclosure is illustrated by way of example and not by way of limitation in the figures of the accompanying drawings, in which like references indicate similar elements. It should be noted that references to “an” or “one” embodiment in this disclosure are not necessarily to the same embodiment, and such references mean “at least one.”

The term “comprising,” when utilized, means “including, but not necessarily limited to”; it specifically indicates open-ended inclusion or membership in the so-described combination, group, series, and the like.

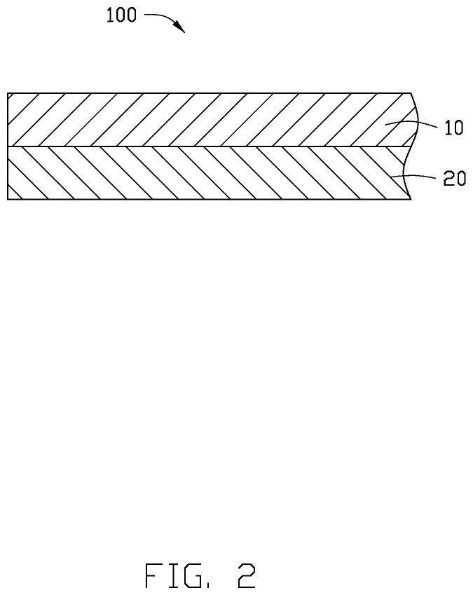

FIG. 2 shows a copper clad laminate 100 of the present disclosure. The copper clad laminate 100 includes a copper layer 10 and a polyimide film 20 attached on the copper layer 10. The polyimide film 20 is made from a polyamic acid composition.

The polyamic acid composition is a polymerization reaction product of dianhydride monomers and diamine monomers.

The dianhydride monomer includes at least one specific functional group structure selected from the combinations of a liquid crystal structure and a soft structure The soft structure may be a long-chain saturated aliphatic hydrocarbon group or a long-chain unsaturated aliphatic hydrocarbon group or an ether group. Among them, the long chain is a hydrocarbon linear structure of four or more carbons.

In at least one embodiment, the soft structure includes at least one of a group such as —O—, —CF₃CCF₃—, —SO₂—, —C═O—, —CₙH₂ₙ—, —CₙH₂ₙ₋₂—, —CₙH₂ₙ₋₄—, n≥3.

The diamine monomers have a combination of specific functional groups containing at least one nitrogen heterocycle structure, at least one liquid crystal structures, and at least one soft structure. The soft structure may be a long-chain saturated aliphatic hydrocarbon group, a long-chain unsaturated aliphatic hydrocarbon group, or an ether group. Among them, the long chain is a hydrocarbon linear structure of four or more carbons. In the at least one embodiment, the soft structure includes at least one of a group such as —O—, —CF₃CCF₃—, —SO₂—, —C═O—, —CₙH₂ₙ—, —CₙH₂ₙ₋₂—, —CₙH₂ₙ₋₄—, n≥3.

The nitrogen atom on the nitrogen heterocycle of the diamine monomer containing nitrogen heterocycles can coordinate with copper ions to improve the bonding strength of the polyimide film 20 and the copper foil 10.

Under a high temperature, the dianhydride monomer or the diamine monomer containing liquid crystal structures can closely arrange liquid crystal structures in the polymer structure of the polyimide to form crystals, thereby reducing the mobility of a molecular structure of polyimide under high frequency electric field, and then reducing the dielectric loss of the polyimide film 20.

The dianhydride monomer or diamine monomer containing soft structures can adjust the rigidity caused by the crystals, and adjust the thermal expansion coefficient (CTE) of the polyimide film 20 to make the polyimide film 20 to match with the copper foil 10 to avoid copper clad warping.

The molar ratio of the dianhydride monomer to the diamine monomer is from 0.9 to 1.1.

The diamine monomer containing at least one liquid crystal structure and the diamine monomer containing at least one soft structure have a molar weight percentage of about 92% to about 97% of a total molar weight of the diamine monomer. The diamine monomer containing liquid crystal structures has a molar weight percentage of about 30% to about 70% of a total molar weight of the diamine monomer containing liquid crystal structures and the diamine monomer containing soft structures; the diamine monomer containing soft structures has a molar weight percentage of about 30% to about 70% of a total molar weight of the diamine monomer containing liquid crystal structures and the diamine monomer containing soft structures; and a sum of the molar weight percentages of the diamine monomer containing liquid crystal structures and the diamine monomer containing soft structures is 100%. The difference of the range of the molar weight percentage or the number of liquid crystal structures or soft structures of the polyamic acid composition may indirectly or directly affect the dielectric loss of the polyimide film 20 and the CTE value of the polyimide film 20.

The diamine monomer containing nitrogen heterocycles has a molar weight percentage of about 3% to about 8% of the total molar weight of the diamine monomer, ensuring that a polyimide film made by the polyamic acid composition has a high adhesion strength and a high transparency. Experiment shows that, when the diamine monomer containing nitrogen heterocycles has a molar weight percentage more than 8% of the total molar weight of the diamine monomer, an increasing rate of the adhesion strength of the polyimide film decrease, while the transparency of the polyimide film is decreased because of a high charge transfer effect during the process of the diamine monomer containing nitrogen heterocycles absorbing light.

In at least one embodiment, the liquid crystal structures may be, but not limited to at least one of

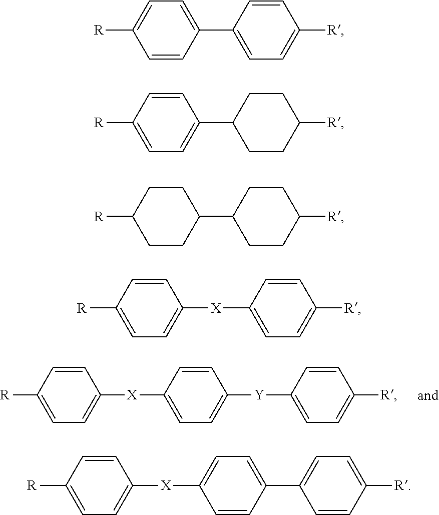

R and R′ are a hydrocarbon group, and X and Y are at least one of —CH═CH—, —C≡C—, —CH═N—, —CH═N—, and —COO—.

In at least one embodiment, the dianhydride monomer containing liquid crystal structures is aromatic tetracarboxylic dianhydride. Further, the dianhydride monomer containing liquid crystal structures may be, but not limited to at least one of 3,3′,4,4′-biphenyltetracarboxylic dianhydride (CAS: 2420-87-3), p-phenylene bis(trimellitate) dianhydride (TAHQ, CAS: 2770-49-2), and cyclohexane-1,4-diylbis(methylene)bis(1,3-dioxo-1,3-dihy-droisobenzofuran-5-carboxylate (TA-CHDM).

A chemical structure formula of the 3,3′,4,4′-biphenyltetracarboxylic dianhydride is:

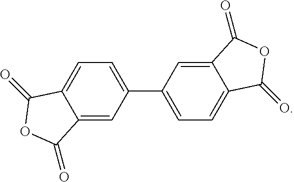 [SMILES: O=C1OC(=O)c2cc(-c3ccc4c(c3)C(=O)OC4=O)ccc21]

A chemical structure formula of the p-phenylene bis(trimellitate) dianhydride is:

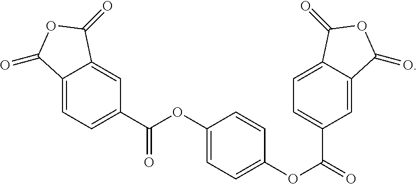 [SMILES: O=C(Oc1ccc(OC(=O)c2ccc3c(c2)C(=O)OC3=O)cc1)c1ccc2c(c1)C(=O)OC2=O]

A chemical structure formula of the cyclohexane-1,4-diylbis(methylene)bis(1,3-dioxo-1,3-dihy-droisobenzofuran-5-carboxylate is:

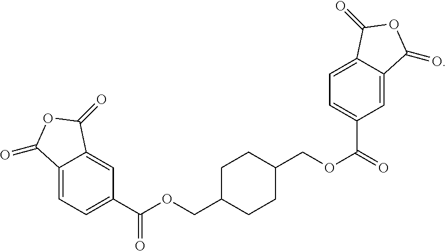 [SMILES: O=C(OCC1CCC(COC(=O)c2ccc3c(c2)C(=O)OC3=O)CC1)c1ccc2c(c1)C(=O)OC2=O]

In at least one embodiment, the diamine monomer containing liquid crystal structures may be, but not limited to at least one of 4-aminobenzoic acid 4-aminophenyl ester (APAB; CAS: 20610-77-9), (1,4-bis(4-aminobenzo-yloxy)benzene (ABHQ; CAS: 22095-98-3), and (1,4-benzenedicarboxylic acid bis(4-aminophenyl) ester (BPTP; CAS: 16926-73-1).

A chemical structure formula of the APAB is:

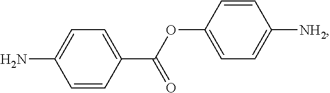 [SMILES: Nc1ccc(OC(=O)c2ccc(N)cc2)cc1]

a chemical structure formula of the ABHQ is:

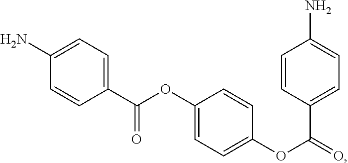 [SMILES: Nc1ccc(C(=O)Oc2ccc(OC(=O)c3ccc(N)cc3)cc2)cc1]

and a chemical structure of the BPTP is:

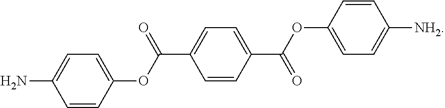 [SMILES: Nc1ccc(OC(=O)c2ccc(C(=O)Oc3ccc(N)cc3)cc2)cc1]

In at least one embodiment, the dianhydride monomer containing soft structures is an aromatic tetracarboxylic dianhydride. Further, the dianhydride monomer containing soft structures can be at least one of 4,4′-oxydiphthalic anhydride (ODPA; CAS: 1823-59-2), 3,4′-oxydiphthalic Anhydride (A-ODPA; CAS: 50662-95-8), benzophenone-3,3′,4,4′-tetracarboxylic dianhydride (BTDA; CAS: 2421-28-5), 3,3′,4,4′-diphenylsulfonetetracarboxylic dianhydride (DSDA; CAS: 2540-99-0), 4,4′-(hexafluoroisopropylidene)diphthalic anhydride (6FDA; CAS: 1107-00-2), and (4,4′-(4,4′-isopropylidenediphenoxy)bis-(phthalic anhydride) (BPADA; CAS: 38103-06-9).

A chemical structure formula of the ODPA is:

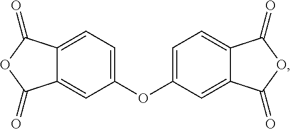 [SMILES: O=C1OC(=O)c2cc(Oc3ccc4c(c3)C(=O)OC4=O)ccc21]

the structure formula of the A-ODPA is:

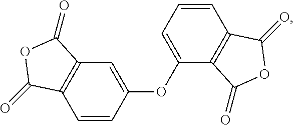 [SMILES: O=C1OC(=O)c2cc(Oc3cccc4c3C(=O)OC4=O)ccc21]

a chemical structure formula of the BTDA is:

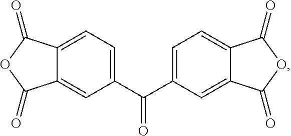 [SMILES: O=C(c1ccc2c(c1)C(=O)OC2=O)c1ccc2c(c1)C(=O)OC2=O]

a chemical structure formula of the DSDA is:

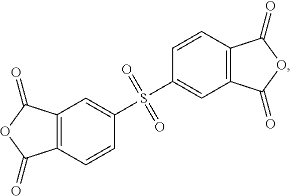 [SMILES: O=C1OC(=O)c2cc(S(=O)(=O)c3ccc4c(c3)C(=O)OC4=O)ccc21]

a chemical structure formula of the 6FDA is:

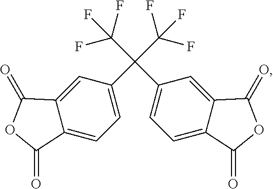 [SMILES: O=C1OC(=O)c2cc(C(c3ccc4c(c3)C(=O)OC4=O)(C(F)(F)F)C(F)(F)F)ccc21]

and a chemical structure formula of the BPADA is:

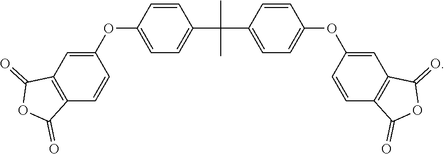 [SMILES: CC(C)(c1ccc(Oc2ccc3c(c2)C(=O)OC3=O)cc1)c1ccc(Oc2ccc3c(c2)C(=O)OC3=O)cc1]

In at least one embodiment, the diamine monomer containing soft structures may be, but not limited to at least one of 4,4′-Oxydianiline (ODA; CAS: 101-80-4), 4,4′-Bis(4-aminophenoxy)biphenyl (BAPB CAS: 13080-85-8), 4,4′-(4,4′-Isopropylidenediphenyl-1,1′-diyldioxy)dianiline (m-BAPP; CAS: 13080-86-9), 2,2-bis[4-(4-aminophenoxy)phenyl]hexafluoropropane (HFBAPP; CAS: 69563-88-8), 4,4′-(1,3-Phenylenedioxy)dianiline (TPE-R CAS: 2479-46-1), 1,3-Bis(3-aminophenoxy)benzene (TPE-M; CAS: 10526-07-5), a diamine having industrial grades D230 and D400, a diamine having a industrial grade DA-C6, and hexamethylenediamine.

A chemical structure formula of the ODA is:

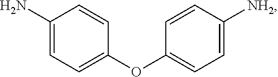 [SMILES: Nc1ccc(Oc2ccc(N)cc2)cc1]

a chemical structure formula of the BAPB is:

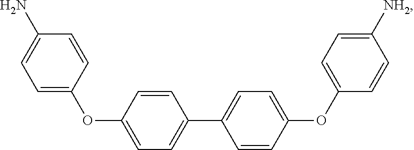 [SMILES: Nc1ccc(Oc2ccc(-c3ccc(Oc4ccc(N)cc4)cc3)cc2)cc1]

a chemical structure formula of the m-BAPP is:

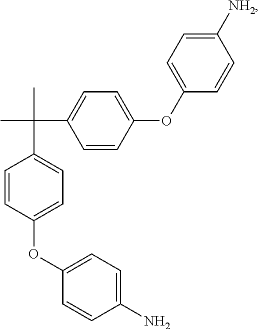 [SMILES: CC(C)(c1ccc(Oc2ccc(N)cc2)cc1)c1ccc(Oc2ccc(N)cc2)cc1]

a chemical structure formula of the HFBAPP is:

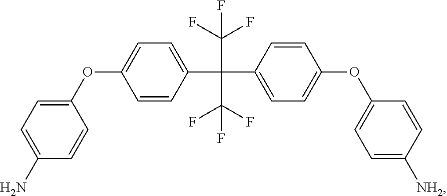 [SMILES: Nc1ccc(Oc2ccc(C(c3ccc(Oc4ccc(N)cc4)cc3)(C(F)(F)F)C(F)(F)F)cc2)cc1]

a chemical structure formula of the TPE-R is:

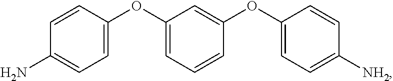 [SMILES: Nc1ccc(Oc2cccc(Oc3ccc(N)cc3)c2)cc1]

a chemical structure formula of the TPE-M is:

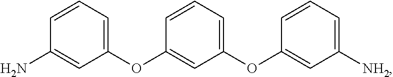 [SMILES: Nc1cccc(Oc2cccc(Oc3cccc(N)c3)c2)c1]

a chemical structure formula of the diamine having industrial grades D230 and D400 is:

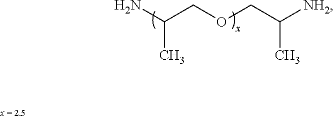

a chemical structure formula of the diamine having a industrial grade DA-C6 is:

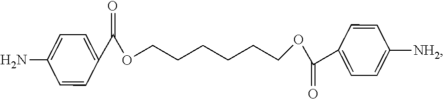 [SMILES: Nc1ccc(C(=O)OCCCCCCOC(=O)c2ccc(N)cc2)cc1]

and a chemical structure formula of the hexamethylenediamine is:

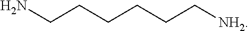

In at least one embodiment, the diamine monomer containing nitrogen heterocycles may be, but not limited to at least one of 1,2,4-triazole-3,5-diamine (DTZ; CAS: 1455-77-2), 2-(4-Aminophenyl)-1h-benzimidazol-5-amine (APBIA; CAS: 7621-86-5), and 4,4′-pyrimidine-2,5-diyldianiline (PRM; CAS: 102570-64-9).

A chemical structure formula of the DTZ is:

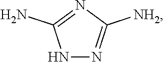

a chemical structure formula of the APBIA is:

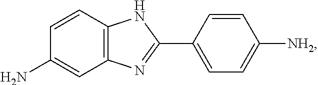 [SMILES: Nc1ccc(-c2nc3cc(N)ccc3[nH]2)cc1]

and a chemical structure formula of the PRM is:

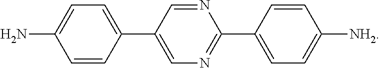 [SMILES: Nc1ccc(-c2cnc(-c3ccc(N)cc3)nc2)cc1]

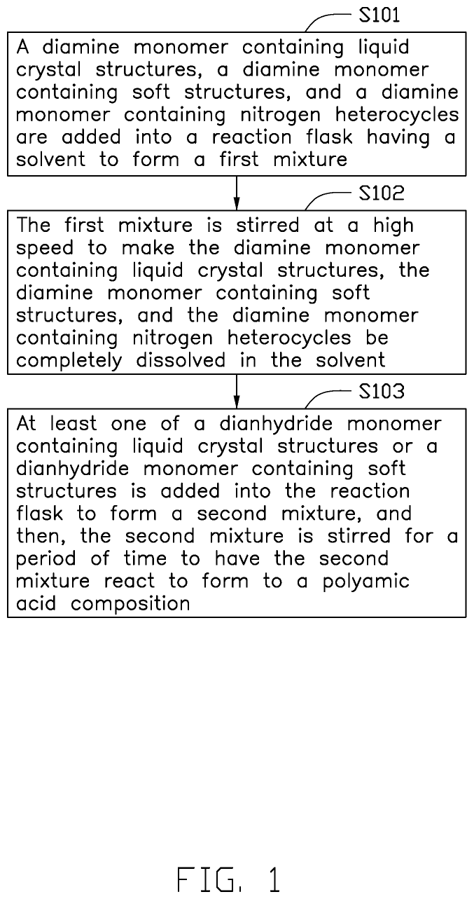

FIG. 1 illustrates a flowchart of a method for manufacturing the polyamic acid in accordance with an exemplary embodiment. The exemplary method is provided by way of example, as there are a variety of ways to carry out the method. Each block shown in the figure represents one or more processes, methods, or subroutines, carried out in the exemplary method. Furthermore, the illustrated order of blocks is by example only and the order of the blocks can change. Additional blocks may be added or fewer blocks may be utilized, without departing from this disclosure. The exemplary method may begin at block 101.

At block 101, a diamine monomer containing liquid crystal structures, a diamine monomer containing soft structures, and a diamine monomer containing nitrogen heterocycles are added into a reaction flask having a solvent to form a first mixture.

At block 102, the first mixture is stirred at a high speed to make the diamine monomer containing liquid crystal structures, the diamine monomer containing soft structures, and the diamine monomer containing nitrogen heterocycles be completely dissolved in the solvent. In at least one embodiment, the stirring speed is 1400 rpm.

At block 103, at least one of a dianhydride monomer containing liquid crystal structures or a dianhydride monomer containing soft structures is added into the reaction flask to form a second mixture, and then, the second mixture is stirred for a period of time to have the second mixture react to form to a polyamic acid composition.

The solvent is a bipolar aprotic solvent. In at least one embodiment, the bipolar aprotic solvent may be selected from a group consisting of bimethyl formamide (DMF), dimethyl acetamide (DMAC), N-Methylpyrrolidone (NMP), dimethyl sulfoxide (DMSO), or any combination thereof. The amount of the solvent may be adjusted, ensuring that all the above components may be dissolved in the solvent.

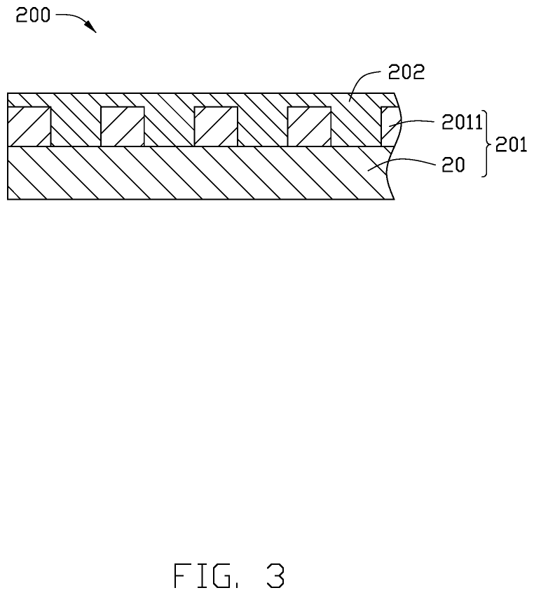

Referring to FIGS. 2-3, the copper clad laminate 100 is used to make a printed circuit board 200. The copper layer 10 has a low surface roughness. In at least one embodiment, the surface roughness of the copper layer 10 has a range from 0.12 um to 2.1 um. The polyimide film 20 is formed by coating the polyamic acid composition on the copper foil 10, and then cyclizing at a high temperature.

A principle of a cyclizing reaction at a high temperature to form the polyimide film 20 is as follows:

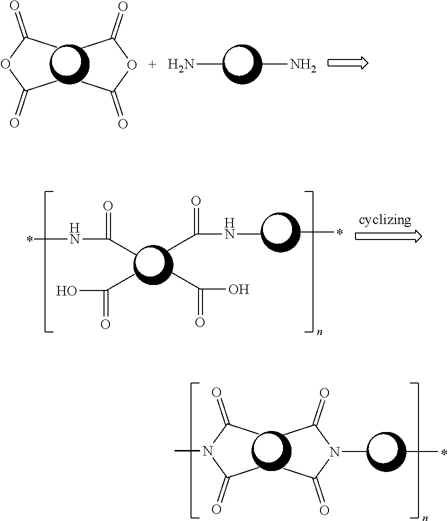

As the polyamic acid composition includes the diamine monomer containing nitrogen heterocycles, and the nitrogen atom on the nitrogen heterocycle of the diamine monomer containing nitrogen heterocycles can coordinate with copper ions in a connecting surface of the copper foil 10, thereby the polyamic acid composition has strong binding force with the copper foil 10. The polyimide film 20 thereby formed by the polyamic acid composition has a strong binding force with the copper foil 10. The connecting surface of the copper foil 10 has a low surface roughness, thereby a surface of the polyimide film 20 formed on the connecting surface is smooth, thereby the polyimide film 20 has a high transparency.

The copper foil 10 is directly bonded to the polyimide film 20, and an adhesive layer is not disposed between the copper foil 10 and the polyimide film 20. Thus, the transparency of the polyimide film 20 can be further improved, and cost can be saved.

A polyimide film 20, the polyimide film 20 is formed by coating the polyamic acid composition on a base layer (such as the copper foil 10), and then cyclizing at a high temperature;

A method for making the copper clad laminate 100 including the following steps:

Firstly, a copper foil 10 is provided. The copper layer 10 has a low surface roughness. In at least one embodiment, the surface roughness of the copper layer 10 has a range from 0.12 um to 2.1 um.

Secondly, a polyamic acid composition is provided. The polyamic acid composition is a condensation reaction product of a dianhydride monomer and a diamine monomer. The dianhydride monomer includes at least one of a dianhydride monomer containing liquid crystal structures or a dianhydride monomer containing soft structures. The diamine monomer includes a diamine monomer containing liquid crystal structures, a diamine monomer containing soft structures, and a diamine monomer containing nitrogen heterocycles.

Thirdly, the polyamic acid composition is coated on a connecting surface of the copper foil 10.

Fourthly, the polyamic acid composition coated on the connecting surface is cyclized at a high temperature of about 300 degrees Celsius to about 400 degrees Celsius, to have the polyamic acid composition dehydrate and close loops, thereby forming a polyimide film 20 on the connecting surface of the copper foil 10, thereby forming the copper clad laminate 100.

FIG. 2 illustrates an embodiment of a printed circuit board 200. The printed circuit board 200 includes a circuit substrate 201, a covering film 202 attached to at least one surface of the circuit substrate 201, and at least one electronic component (not shown).

The circuit substrate 201 includes a polyimide film 20, and a conductive circuit layer 2011 attached to at least one surface of the polyimide film 20. The conductive circuit layer 2011 is formed by etching the copper foil 10 of the copper clad laminate 100. The covering film 202 is attached to the surface of the conductive circuit layer 2011 away from the polyimide film 20.

### Example 1

NMP (203.37 g), APAB (0.068 mol, 15.52 g), ODA (0.027 mol, 5.41 g), and DTZ (0.005 mol, 0.50 g) are added into a reaction flask (500 ml) having a solvent to form a first mixture. The first mixture is stirred at a high speed to make the APAB, ODA, and DTZ be completely dissolved in the NMP. BPDA (0.1 mol, 29.42 g) is added into the reaction flask to form a second mixture. The second mixture is stirred for 48 hours at a temperature that is lower than a room temperature, and under anhydrous nitrogen to have the second mixture react to form to a polyamic acid composition.

### Example 2

NMP (205.77 g), APAB (0.078 mol, 17.80 g), ODA (0.017 mol, 3.40 g), and DTZ (0.005 mol, 0.50 g) are added into a reaction flask (500 ml) having a solvent to form a first mixture. The first mixture is stirred at a high speed to make the APAB, ODA, and DTZ be completely dissolved in the NMP. ODPA (0.02 mol, 6.20 g) and BPDA (0.08 mol, 23.54 g) are added into the reaction flask to form a second mixture. The second mixture is stirred for 48 hours at a temperature that is lower than a room temperature, and under anhydrous nitrogen to have the second mixture react to form to a polyamic acid composition.

### Example 3

NMP (250.75 g), APAB (0.045 mol, 10.27 g), ODA (0.060 mol, 12.01 g), DTZ 0.005 mol, 0.50 g) are added into a reaction flask (500 ml) having a solvent to form a first mixture. The first mixture is stirred at a high speed to make the APAB, ODA, and DTZ be completely dissolved in the NMP. ODPA (0.04 mol, 12.41 g), TAHQ (0.06 mol, 27.50 g) are added into the reaction flask to form a second mixture. The second mixture is stirred for 48 hours at a temperature that is lower than a room temperature, and under anhydrous nitrogen to have the second mixture react to form to a polyamic acid composition.

### Example 4

NMP (211.68 g), APAB (0.085 mol, 19.40 g), ODA (0.010 mol, 2.00 g), DTZ (0.005 mol, 0.50 g) are added into a reaction flask (500 ml) having a solvent to form a first mixture. The first mixture is stirred at a high speed to make the APAB, ODA, and DTZ be completely dissolved in the NMP. ODPA (0.1 mol, 31.02 g) is added into the reaction flask to form a second mixture. The second mixture is stirred for 48 hours at a temperature that is lower than a room temperature, and under anhydrous nitrogen to have the second mixture react to form to a polyamic acid composition.

### Comparative Example 1

NMP (170.66 g), PDA (0.068 mol, 7.34 g), ODA (0.027 mol, 5.41 g), DTZ (0.005 mol, 0.50 g) are added into a reaction flask (500 ml) having a solvent to form a first mixture. The first mixture is stirred at a high speed to make the PDA, ODA, and DTZ be completely dissolved in the NMP. BPDA (0.1 mol, 29.42 g) is added into the reaction flask to form a second mixture. The second mixture is stirred for 48 hours at a temperature that is lower than a room temperature, and under anhydrous nitrogen to have the second mixture react to form to a polyamic acid composition.

### Comparative Example 2

NMP (205.61 g), APAB (0.070 mol, 15.98 g), and ODA (0.030 mol, 6.01 g) are added into a reaction flask (500 ml) having a solvent to form a first mixture. The first mixture is stirred at a high speed to make the APAB and ODA be completely dissolved in the NMP. BPDA (0.1 mol, 29.42 g) is added into the reaction flask to form a second mixture. The second mixture is stirred for 48 hours at a temperature that is lower than a room temperature, and under anhydrous nitrogen to have the second mixture react to form to a polyamic acid composition.

### Comparative Example 3

NMP (263.41 g) and ODA (0.1 mol, 20.02 g) are added into a reaction flask (500 ml) having a solvent to form a first mixture. The first mixture is stirred at a high speed to make the ODA be completely dissolved in the NMP. TAHQ (0.1 mol, 45.83 g) is added into the reaction flask to form a second mixture. The second mixture is stirred for 48 hours at a temperature that is lower than a room temperature, and under anhydrous nitrogen to have the second mixture react to form to a polyamic acid composition.

### Comparative Example 4

NMP (208.98 g) and APAB (0.1 mol, 22.83 g) are added into a reaction flask (500 ml) having a solvent to form a first mixture. The first mixture is stirred at a high speed to make the APAB be completely dissolved in the NMP. BPDA (0.1 mol, 29.42 g) is added into the reaction flask to form a second mixture. The second mixture is stirred for 48 hours at a temperature that is lower than a room temperature, and under anhydrous nitrogen to have the second mixture react to form to a polyamic acid composition.

Copper clad laminates 100 were formed by the polyamic acid compositions of the examples 1˜4 and the comparative examples 1-4.

The copper clad laminates 100 were subjected to a peel strength test, a solder float resistance test, a coefficient of thermal expansion (CTE) test, a thermogravimetric test (Tg), a dielectric constant (Dₖ) test, and a dielectric loss (D_{f}) test, respectively. The test results are shown in table 1.

The solder float resistance test was carried out by forming solder masks on the surface of the polyimide film, then exposing the copper clad laminates to a temperature equal to or greater than 288 degrees Celsius for 10 seconds, and observing whether the solder masks were peeled off or dropped from the copper clad laminates.

TABLE 1

| | | EXAM- | EXAM- | EXAM- | EXAM- | | | | |
|---|---|---|---|---|---|---|---|---|---|
| | | PLE | PLE | PLE | PLE | COMPARATIVE | COMPARATIVE | COMPARATIVE | COMPARATIVE |
| | | 1 [symbol] | 2 [symbol] | 3 [symbol] | 4 [symbol] | EXAMPLE 1 [symbol] | EXAMPLE 2 [symbol] | EXAMPLE 3 [symbol] | EXAMPLE 4 [symbol] |
| composition | APAB [symbol] | [symbol] | [symbol] | [symbol] | [symbol] | [symbol] | [symbol] | [symbol] | [symbol] |
| | PDA [symbol] | [symbol] | [symbol] | [symbol] | [symbol] | [symbol] | [symbol] | [symbol] | [symbol] |
| | ODA [symbol] | [symbol] | [symbol] | [symbol] | [symbol] | [symbol] | [symbol] | [symbol] | [symbol] |
| | DTZ [symbol] | [symbol] | [symbol] | [symbol] | [symbol] | [symbol] | [symbol] | [symbol] | [symbol] |
| | TAHQ [symbol] | [symbol] | [symbol] | [symbol] | [symbol] | [symbol] | [symbol] | [symbol] | [symbol] |
| | BPDA [symbol] | [symbol] | [symbol] | [symbol] | [symbol] | [symbol] | [symbol] | [symbol] | [symbol] |
| | ODPA [symbol] | [symbol] | [symbol] | [symbol] | [symbol] | [symbol] | [symbol] | [symbol] | [symbol] |

| | | | | | | | | |
|---|---|---|---|---|---|---|---|---|
| peel strength [symbol] | [symbol] | [symbol] | [symbol] | [symbol] | [symbol] | [symbol] | [symbol] | [symbol] |
| solder float resistance | pass [symbol] | pass [symbol] | pass [symbol] | pass [symbol] | pass [symbol] | pass [symbol] | pass [symbol] | pass [symbol] |
| test [symbol] | | | | | | | | |
| Tg (° C.) [symbol] | [symbol] | [symbol] | [symbol] | [symbol] | [symbol] | [symbol] | [symbol] | [symbol] |
| CTE (ppm/° C.) [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] |
| [symbol] | [symbol] | [symbol] | [symbol] | [symbol] | [symbol] | [symbol] | [symbol] | [symbol] |

[symbol]

indicates data missing or illegible when filed

As can be seen from the table 1, examples 1 to 4 are the present disclosure for including a dianhydride monomer containing liquid crystal structures and a diamine monomer containing nitrogen heterocycles, which still retain good peel strength with copper foil and can lower the dielectric loss D_{f} value from 0.004 to 0.006, and comparative example 1 has a dielectric loss D_{f} value of 0.014, because it did not contain a dianhydride monomer containing liquid crystal structures. In comparative Examples 2 to 4, since the dianhydride monomer containing liquid crystal structures was contained, the peeling strength with the copper foil was extremely lowered, due to the lack of the diamine monomer containing nitrogen heterocycles. In comparative example 3, the diamine monomer containing soft structures was only used, and the CTE value was large that caused warpage of the copper clad laminate. In comparative example 4, the diamine monomer containing soft structures was not used, and the CTE value was low, that caused the copper clad plate to warp.

With the above configuration, the polyamic acid composition is a condensation reaction product of a dianhydride monomer and a diamine monomer. The dianhydride monomer includes at least one of a dianhydride monomer containing liquid crystal structures or a dianhydride monomer containing soft structures. The diamine monomer includes a diamine monomer containing liquid crystal structures, a diamine monomer containing soft structures, and a diamine monomer containing nitrogen heterocycles. The nitrogen atom on the nitrogen heterocycle of the diamine monomer containing nitrogen heterocycles can coordinate with copper ions to improve the bonding strength of the polyimide film 20 and the copper foil 10. Under a high temperature, the dianhydride monomer or the diamine monomer containing liquid crystal structures can closely arrange liquid crystal structures in the polymer structure of the polyimide to form crystals, thereby reducing the mobility of a molecular structure of polyimide under high frequency electric field, and then reducing the dielectric loss of the polyimide film 20. The dianhydride monomer or diamine monomer containing soft structures can adjust the rigidity caused by the crystals, and adjust the thermal expansion coefficient (CTE) of the polyimide film 20 to make the polyimide film 20 to match with the copper foil 10 to avoid copper clad warping.

The embodiments shown and described above are only examples. Many details are often found in the relevant art, thus many such details are neither shown nor described. Even though numerous characteristics and advantages of the present disclosure have been set out in the foregoing description, together with details of the structure and function of the present disclosure, the disclosure is illustrative only, and changes can be made in the detail, including in matters of shape, size, and arrangement of the parts within the principles of the present disclosure, up to and including the full extent established by the broad general meaning of the terms used in the claims. It will therefore be appreciated that the embodiments described above can be modified within the scope of the claims.

What is claimed is:

1. A polyamic acid composition is polymerized by dianhydride monomers and diamine monomers, wherein a range of molar ratio of the dianhydride monomers to the diamine monomers is from 0.9 to 1.1; wherein the diamine monomers have a combination of specific functional groups containing at least one nitrogen heterocycle structure, at least one liquid crystal structure, and at least one soft structure, wherein the diamine monomer containing nitrogen heterocycle structure has a molar weight percentage of 3% to 8% of a total molar weight of the diamine monomers, and the diamine monomers containing at least one liquid crystal structure and at least one soft structure have a molar weight percentage of 92% to 97% of the total molar weight of the diamine monomers.

2. The polyamic acid composition of claim 1, wherein the dianhydride monomer comprise at least one specific functional group structure selected from the combinations of a liquid crystal structure and a soft structure.

3. The polyamic acid composition of claim 1, wherein the diamine monomer containing liquid crystal structure has a molar weight percentage of 30% to 70% of a total molar weight of the diamine monomer containing liquid crystal structure and the diamine monomer containing soft structure; the diamine monomer containing soft structure has a molar weight percentage of 30% to 70% of a total molar weight of the diamine monomer containing liquid crystal structure and the diamine monomer containing soft structure; and a sum of the molar weight percentages of the diamine monomer containing liquid crystal structure and the diamine monomer containing soft structure is 100%.

4. The polyamic acid composition of claim 1, wherein the soft structure is a long-chain saturated aliphatic hydrocarbon group, a long-chain unsaturated aliphatic hydrocarbon group, or an ether group.

5. The polyamic acid composition of claim 2, wherein the soft structure is a long-chain saturated aliphatic hydrocarbon group, a long-chain unsaturated aliphatic hydrocarbon group, or an ether group.

6. The polyamic acid composition of claim 4, wherein the soft structure comprises at least one of a group —O—, —CF₃CCF₃—, —C═O—, —CₙH₂ₙ—, —CₙH₂ₙ₋₂—, —CₙH₂ₙ₋₄—, wherein n≥3.

7. The polyamic acid composition of claim 5, wherein the soft structure comprises at least one of a group —O—, —CF₃CCF₃—, —SO₂—, —C═O—, —CₙH₂ₙ—, —CₙH₂ₙ₋₂—, —CₙH₂ₙ₋₄—, wherein n≥3.

8. The polyamic acid composition of claim 1, wherein the liquid crystal structures are at least one of: 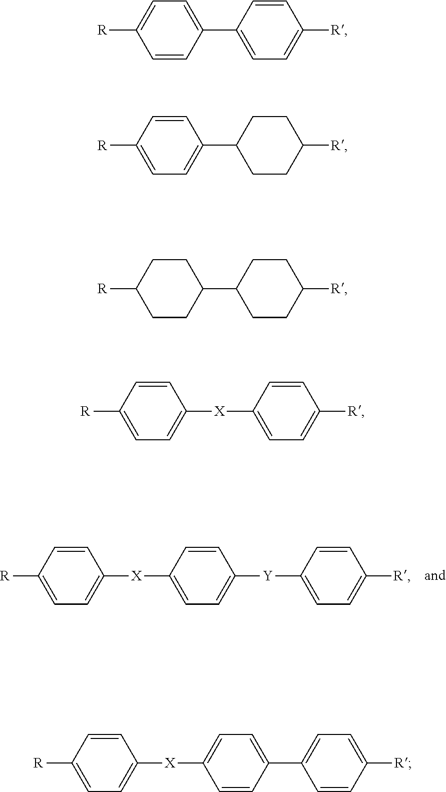
wherein R and R′ are a hydrocarbon group; and X and Y are at least one of —CH═CH—, —C≡C—, —CH═N—, —CH═N—, and —COO—.

9. The polyamic acid composition of claim 2, wherein the liquid crystal structures are at least one of: 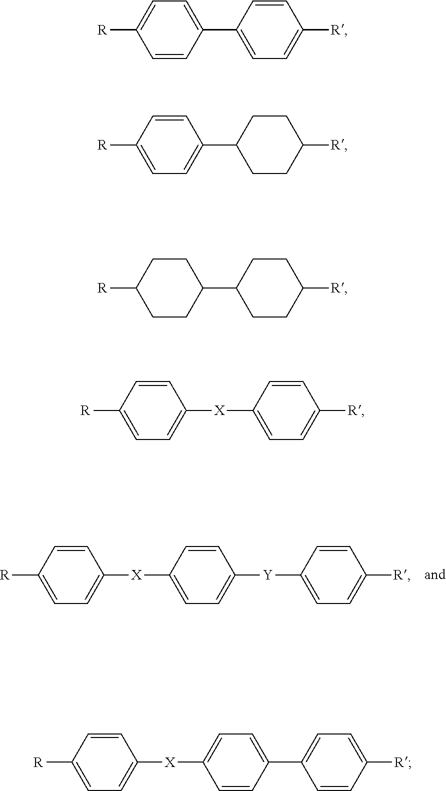
wherein R and R′ are a hydrocarbon group; and X and Y are at least one of —CH═CH—, —C≡C—, —CH═N—, —CH═N—, and —COO—.

10. The polyamic acid composition of claim 8, wherein the diamine monomer containing liquid crystal structures is at least one of 4-aminobenzoic acid 4-aminophenyl ester, (1,4-bis(4-aminobenzo-yloxy)benzene, and (1,4-benzenedicarboxylic acid bis(4-aminophenyl) ester.

11. The polyamic acid composition of claim 9, wherein the dianhydride monomer containing liquid crystal structures is at least one of 3,3′,4,4′-biphenyltetracarboxylic dianhydride, p-phenylene bis(trimellitate) dianhydride, and cyclohexane-1,4-diylbis(methylene)bis(1,3-dioxo-1,3-dihy-droisobenzofuran-5-carboxylate.

12. The polyamic acid composition of claim 4, wherein the diamine monomer containing soft structures is at least one of 4,4′-oxydianiline, 4,4′-Bis(4-aminophenoxy)biphenyl, 4,4′-(4,4′-isopropylidenediphenyl-1,1′-diyldioxy)dianiline, 2,2-bis[4-(4-aminophenoxy)phenyl]hexafluoropropane, 4,4′-(1,3-Phenylenedioxy)dianiline, 1,3-Bis(3-aminophenoxy)benzene, a diamine having industrial grades D230 and D400, a diamine having a industrial grade DA-C6, and hexamethylenediamine.

13. The polyamic acid composition of claim 5, wherein the dianhydride monomer containing soft structures is at least one of 4,4′-oxydiphthalic anhydride, 3,4′-oxydiphthalic Anhydride, benzophenone-3,3′,4,4′-tetracarboxylic dianhydride, 3,3′,4,4′-diphenylsulfonetetracarboxylic dianhydride, 4,4′-(hexafluoroisopropylidene)diphthalic anhydride, and (4,4′-(4,4′-isopropylidenediphenoxy)bis-(phthalic anhydride).

14. The polyamic acid composition of claim 1, wherein the diamine monomer containing nitrogen heterocycles is at least one of 1,2,4-triazole-3,5-diamine, 2-(4-Aminophenyl)-1h-benzimidazol-5-amine, and 4,4′-pyrimidine-2,5-diyldianiline.

15. A polyimide film, wherein the polyimide film is made from a polyamic acid composition; the polyamic acid composition is polymerized by dianhydride monomers and diamine monomers, wherein a range of molar ratio of the dianhydride monomers to the diamine monomers is from 0.9 to 1.1; wherein the diamine monomers have a combination of specific functional groups containing at least one nitrogen heterocycle structure, at least one liquid crystal structure, and at least one soft structure, wherein the diamine monomer containing nitrogen heterocycle structure has a molar weight percentage of 3% to 8% of a total molar weight of the diamine monomers, and the diamine monomers containing at least one liquid crystal structure and at least one soft structure have a molar weight percentage of 92% to 97% of the total molar weight of the diamine monomers.

16. The polyimide film of claim 15, wherein the dianhydride monomer comprise at least one specific functional group structure selected from the combinations of a liquid crystal structure and a soft structure.

17. The copper clad laminate of claim 15, wherein the diamine monomer containing liquid crystal structures has a molar weight percentage of 30% to 70% of a total molar weight of the diamine monomer containing liquid crystal structures and the diamine monomer containing soft structures; the diamine monomer containing soft structures has a molar weight percentage of 30% to 70% of a total molar weight of the diamine monomer containing liquid crystal structures and the diamine monomer containing soft structures; and a sum of the molar weight percentages of the diamine monomer containing liquid crystal structures and the diamine monomer containing soft structures is 100%.

18. The copper clad laminate of claim 15, wherein the soft structure is a long-chain saturated aliphatic hydrocarbon group, a long-chain unsaturated aliphatic hydrocarbon group, or an ether group.

19. A copper clad laminate, comprising:
a copper layer; and
a polyimide film; wherein the polyimide film made from a polyamic acid composition; the polyamic acid composition is polymerized by dianhydride monomers and diamine monomers, wherein a range of molar ratio of the dianhydride monomers to the diamine monomers is from 0.9 to 1.1; wherein the diamine monomers have a combination of specific functional groups containing at least one nitrogen heterocycle structure, at least one liquid crystal structure, and at least one soft structure, wherein the diamine monomer containing nitrogen heterocycle structure has a molar weight percentage of 3% to 8% of a total molar weight of the diamine monomers, and the diamine monomers containing liquid crystal structure and soft structure have a molar weight percentage of 92% to 97% of the total molar weight of the diamine monomers.

20. The copper clad laminate of claim 19, wherein the dianhydride monomer comprise at least one specific functional group structure selected from the combinations of a liquid crystal structure and a soft structure.
